(19) United States
(12) Patent Application Publication
(10) Pub. No.: US 2024/0158905 A1
(43) Pub. Date: May 16, 2024

(54) PROTECTIVE COATING FOR A COPPER ALLOW SUBSTRATE AND CORRESPONDING PROCESS

(71) Applicant: COEURDOR, Maiche (FR)

(72) Inventors: Nicolas BAILLY, Besancon (FR); Frederic CHEMERY, Rurey (FR); Etienne FIZAINE, Morre (FR); Jean-Marc CATTENOT, Belmont (FR)

(21) Appl. No.: 18/546,897

(22) PCT Filed: Feb. 16, 2022
(86) PCT No.: PCT/EP22/53816

§ 371 Date: Aug. 17, 2023

(30) Foreign Application Priority Data
Feb. 17, 2021 (FR) FR2101496

(51) Int. Cl. C23C 14/02; C23C 14/16; C23C 14/34; C23C 14/58

(52) U.S. Cl. CPC C23C 14/025; C23C 14/021; C23C 14/16; C23C 14/34; C23C 14/5853

(57) ABSTRACT

A protective coating for a copper alloy substrate includes a layer of a transition metal, referred to as primer layer, and a corrosion protection layer formed by at least one portion of the primer layer. The primer layer includes the transition metal combined with an oxidized transition metal. A process for depositing the protective coating is by physical vapor deposition (PVD) technology. The substrate is positioned in a chamber, with a target made of a transition metal, the chamber being supplied with various gases. The substrate is dehumidified and descaled. A thin primer layer of transition metal is deposited on substrate and bombarded with a mixture of argon ions and oxygen ions. A corrosion protection layer is formed by oxidizing the transition metal of the primer layer.

### CROSS-REFERENCE TO RELATED APPLICATIONS

See Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

### 1. Field of the Invention

The technical field relates to that of protective coatings deposited on a substrate, more specifically protective coatings for a copper alloy substrate, that is to say formed at least on the surface of a copper alloy, in particular a brass or a bronze. The technical field also relates more particularly to protective coatings of a substrate of the brass, bronze or equivalent type, said coating being obtained and/or deposited at least in part by the physical vapor deposition of a thin protective film under vacuum.

The field of the invention further relates to processes for producing and/or depositing such protective coatings on a substrate, in particular formed at least on the surface of a copper alloy, in particular a brass or a bronze. The field of the invention also relates to processes for producing and/or depositing such protective coatings comprising at least one step of physical vapor deposition under vacuum of a thin protective film.

### 2. Description of Related Art Including Information Disclosed Under 37 CFR 1.97 and 37 CFR 1.98

Producing a metal object requires having a metal that is easy to work with and shape. It has been known to use copper, which is easy to work with, since ancient times. But copper's ductility is an advantage and a drawback when a part having good general mechanical strength is sought. In addition, copper can corrode easily.

To remedy this, copper alloys, in particular those commonly called brass, have been developed, mainly comprising a mixture of copper (chemical symbol Cu) and zinc (chemical symbol Zn), or alloys commonly called bronze, mainly comprising a mixture of copper (chemical symbol Cu) and tin (chemical symbol Sn).

Copper alloy refers to a cupro-alloy, that is an alloy comprising copper in which the copper content is predominant. Such a copper alloy has a lower melting temperature and better mechanical strength than pure copper, while retaining easy implementation and improved corrosion resistance. The corrosion resistance of the alloy reduces corrosion but does not eliminate it, and it is necessary to provide a corrosion protection layer, in particular against galvanic or atmospheric corrosion.

For better clarity of draft, copper alloys of the brass type predominantly comprising copper will be designated by the general term “copper alloy” in the rest of the description and claims. This includes in particular bronzes and brasses.

Copper alloys are commonly used to produce all types of objects, in particular small decorative and aesthetic objects.

These objects made of copper alloy can have their surface completely or partially coated by one or more layers.

This may be one or more decorative layers, but also one or more mechanical protection layers, that is to say a layer having a resistance to mechanical wear and/or impacts and/or scratches that is satisfactory with respect to the expectations of the profession, or even one or more protective layers for said material of the object against corrosion, without of course counting a primer or adhesion layer for the material of the object. For better clarity of drafting, a layer having satisfactory resistance to mechanical wear and/or impacts and/or scratches with respect to the expectations of the profession will be designated by the term “mechanical protective layer” in the rest of the description and claims.

Thus, in the case of brass, for example, it is common for the surface of a brass object to be coated with a primer layer, a scratch protection layer, and a decorative layer.

It is possible, in a known manner, to deposit one or more layers of a thin film using vacuum-phase physical vapor deposition technology, or an ion deposition technology commonly called “ion positioning”.

This physical vapor deposition technology is known more commonly under the acronym PVD. This PVD technology is now widespread in industry.

It allows precise deposition of a thin metallic layer of a metal or a mixture of several metals on a metal substrate. The term “substrate” denotes all or part of a brass object.

Thin layer denotes a layer of less than 10 micrometers, or even sometimes less than 2 micrometers. This PVD is done in the presence of a so-called passive medium, that is under vacuum, or in the presence of a noble gas or so-called rare gas such as argon, whose chemical formula is Ar. This deposition can also be carried out in the presence of a so-called active medium, that is, in the presence of one or more so-called reactive gases, for example in the presence of dioxygen, chemical formula O2, or dinitrogen, chemical formula N2, or in the presence of a plasma, to respectively obtain an oxide or a nitride.

PVD technology consists in using at least one target made of metal or metal alloy, installed with a substrate in a chamber, in producing a reduction in pressure in the chamber, and transferring atoms from the target to the substrate, by passing them through a passive medium or an active medium. The substrate is mounted on a substrate holder, mobile or fixed in the chamber.

A metal target is composed of at least 99.5% of said metal. A metal alloy target is composed of at least 99.5% of a mixture of the metals constituting the corresponding alloy. In the rest of the description and claims, the term target refers to a target made of a metal or an alloy of several metals.

It should be noted that the atoms or molecules can receive an amount of energy in the form of waves until it reaches, in the passive or active environment, a state of plasma. The metal atoms then become metal particles. In the case of an active medium, the metal atoms can also combine with the reactive gases to form more complex particles.

Under the action of electric, magnetic or electromagnetic fields, the particles are accelerated toward the substrate on which they are deposited and/or interact by forming the covalent bonds.

It is thus possible to form a fine layer of at least one metal from at least one target or molecules on the substrate, or a fine layer of at least one metal combined with another metal, or a fine layer of at least one transition metal and at least one atom of a reactive gas on the substrate.

PVD technology is used in a known manner to produce this type of primer layer comprising at least one metal called a transition metal on a substrate. The terms transition metal and transition element denote, according to the definition of International Union of Pure and Applied Chemistry, “An element whose atom has an incomplete d sub-shell, or which can give rise to cations with an incomplete d sub-shell.” This transition metal may in particular be chromium (chemical symbol Cr), titanium (chemical symbol Ti), zirconium (chemical symbol Zr), yttrium (chemical symbol Y), niobium, (chemical symbol Nb), but this may also be tungsten (chemical symbol W), vanadium (chemical symbol V), or tantalum (chemical symbol Ta). In the case of an alloy target of several metals, an alloy of several of the metals listed above may also be used.

The primer layer thus formed on the substrate is fine, of the order of a few micrometers, and ensures good retention of the subsequent layers.

The layer thus formed has in a known manner a columnar microstructure, comprising intercolumnar spaces making this layer porous. This columnar microstructure allows the passage of a liquid, for example human sweat.

This type of primer layer does not therefore make it possible to protect the substrate from corrosion due to the ambient atmosphere or the touch of a person.

In fact, these transition metals have an oxidation-reduction potential also called electrochemical potential different from that of brass. An electrochemical couple or galvanic couple is then formed that is capable of causing a galvanic or electrolytic corrosion reaction in the presence of an electrolyte, such as for example human sweat. This corrosion happened due to the presence of two conducting metals in contact and in the presence of an electrolyte.

For example, the electrochemical potential difference between brass and titanium is about 370 millivolts. It is also possible to measure an electrochemical potential difference between a copper alloy and a transition metal listed above.

Therefore, this type of primer layer formed by a deposition of a thin layer of a transition metal by PVD technology does not only make it possible to protect the substrate from corrosion due to the ambient atmosphere or the touch of a person, but also accentuates the corrosion effect.

This is why the PVD technology is not used directly on copper alloys.

It is also known to produce a primer layer by electroplating.

To remedy this risk of corrosion of a copper alloy substrate, it is known to produce a primer layer by electroplating, to then deposit on said primer layer a protective layer of a metal by electroplating, that is to say dipping in an electrolytic bath. The metal used may be nickel, chemical symbol Ni, but it is known to cause allergies during prolonged contact with the skin of certain users. The metal used may also be a precious metal, such as palladium, chemical symbol Pd, but the cost of such a coating then becomes high.

Once protection against corrosion is carried out by electroplating, it is also possible to form, using PVD technology, a decorative layer, or a hard layer that can protect the substrate from mechanical wear, impacts, or scratches.

All these manipulations are expensive, time-consuming and increase the risks of errors or accidents on the objects in a copper alloy, in particular made of brass or bronze, or during the mounting of the coating layer of said objects made of copper alloy, in particular made of brass or bronze.

### BRIEF SUMMARY OF THE INVENTION

The objective of the invention is therefore to propose a coating that protects a copper alloy substrate, in particular made of brass or bronze, onto which corrosion is applied, which is simple to implement and economical.

Another objective of the invention is to propose a coating for protecting a copper alloy substrate applied to a copper alloy substrate, which can take up the corrosion protection features, said coating comprising anti-corrosion characteristics, optionally resistance to mechanical wear and/or impacts and/or scratches, as well as a decorative aspect similar to the characteristics of the coatings of the prior art.

Another objective of the invention is to propose a process for producing such a protective coating, in particular an anti-corrosion coating, on a copper alloy substrate.

Yet another objective is to propose a process for producing several protective and/or decorative layers on a copper alloy substrate.

To this end, the invention relates to a coating for protecting a copper alloy substrate, said protective coating comprising a primer layer, said primer layer being deposited on said copper alloy substrate, said primer layer being formed by a thin layer of at least one transition metal, said protective coating comprising a corrosion protection layer, characterized by the fact that said corrosion protection layer is formed by at least one part of the primer layer, and in that said at least one part of the primer layer is in the form of a combination of said at least one transition metal and said at least one oxidized transition metal.

This protective coating is produced by PVD technology.

Due to the production of this protective coating by PVD technology, the oxidation of the at least one transition metal is carried out mainly on the surface of the primer layer opposite the substrate to form said corrosion protection layer, in the form of a combination of said at least one transition metal and said at least one oxidized transition metal. However, the primer layer is also oxidized in depth, in a lesser manner.

As a result, the primer layer deposited on said substrate has a percentage of at least one oxidized transition metal relative to at least one transition metal initially deposited, said percentage being minimal, including being able to be zero, in the vicinity of the substrate, said percentage increasing, at least on average, monotonically from said substrate in the direction of the increasing distance to the substrate.

This coating thus obtained has the advantage of having a corrosion protection layer on the surface opposite that of the substrate, formed by a combination of said at least one transition metal and said at least one oxidized transition metal, this corrosion protection layer being a continuation of the primer layer in which the at least one transition metal is oxidized at gradually higher concentrations until said corrosion protection layer is reached.

Thus, the coating obtained does not have any sudden change in composition.

Advantageously, the primer layer has, in proximity to the substrate, a percentage of at least one transition metal oxidized relative to at least one transition metal initially deposited at least of 0%.

Advantageously, the corrosion protection layer has a percentage of at least one transition metal oxidized relative to at least one transition metal initially deposited at a maximum of between 95 and 100%.

Advantageously still, due to the use of argon during PVD technology to oxidize a part of the at least one transition metal, the primer layer comprising a part of at least one oxidized transition metal also comprises argon atoms inserted into the structure of the primer layer and of the corrosion protection layer.

The quantity of argon atoms inserted into said structures is proportional to the percentage of the at least one transition metal oxidized relative to at least one transition metal initially deposited in said structures. This quantity is minimal near the substrate, and increases as the substrate moves away to reach maximum values at the corrosion protection layer.

Indeed, argon is commonly used in PVD technology, as indicated above. Argon may occlude interstitial spaces of the initially columnar structure of the at least one transition metal deposited by PVD. The modified structure no longer has as many interstitial spaces. Furthermore, argon being a chemically inert gas, it does not interact with corrosive chemical agents. The copper alloy is thus better protected from corrosion.

This coating comprises a part of the at least one transition metal in oxidized form. The initially columnar structure of the at least one transition metal is modified and no longer has as many interstitial spaces. The copper alloy is thus better protected from corrosion.

Advantageously, the protective coating comprises a mechanical protective layer, that is to say a layer having resistance to mechanical wear and/or impacts and/or scratches, this mechanical protective layer coating the corrosion protection layer.

Advantageously, the mechanical protective layer comprises an adhesion layer and a functional layer.

Advantageously, the primer layer is a thin layer of the same at least one transition metal as that used to form the primer layer.

Advantageously, the functional layer is a thin layer of a nitride or an oxide or a carbide or an oxycarbide or a nitrogen carbide of a same at least one transition metal as that used to form the primer layer.

Advantageously, the protective coating comprises a decorative layer coating the mechanical protective layer.

Advantageously, the decorative layer comprises at least one aesthetic layer.

Advantageously, the aesthetic layer is a thin layer of a nitride or an oxide or a carbide or an oxycarbide or a nitrogen carbide of the same at least one transition metal than that used to form the primer layer.

Advantageously, the decorative layer also comprises at least one adhesion layer for the aesthetic layer.

Advantageously, the adhesion layer for the aesthetic layer is a thin layer of the same at least one transition metal as that used to form the aesthetic layer.

Advantageously, said at least one transition metal is titanium.

Advantageously, said at least one transition metal is chromium or zirconium or yttrium or niobium or tungsten or vanadium or tantalum.

Advantageously also, said primer layer of said protective coating is formed by a thin layer of an alloy of at least two transition metals from among titanium, chromium, zirconium, yttrium, niobium, tungsten, vanadium, and tantalum.

Advantageously, the protective coating comprises a corrosion protection layer with a thickness of between 0.2 and 1 micrometers, inclusive.

Advantageously, the protective coating comprises a mechanical protective layer having an adhesion layer with a thickness of between 0.05 and 0.2 micrometers, inclusive, and a functional layer with a thickness of between 0.2 and 1 micrometers, inclusive.

Advantageously, the protective coating comprises a decorative layer having an aesthetic layer with a thickness of between 0.2 and 1 micrometers, inclusive.

Advantageously, the protective coating comprises a decorative layer also having an adhesion layer of between 0.05 and 0.2 micrometers, inclusive.

Such a protective coating deposited on a copper alloy substrate, in particular a brass or a bronze, protects said substrate made of copper alloy from corrosion, it may comprise a mechanical protection layer on said corrosion protection layer, and a decorative layer on said corrosion protection layer, or on the mechanical protection layer if such a layer coats said corrosion protection layer.

Using layers comprising a single transition metal makes it possible to simplify the creation of the protective coating.

This coating makes it possible to protect objects made of copper-based alloy on which it is deposited against corrosion. Thus, these objects coated with this coating have excellent resistance to body sweat after a 24-hour test. Furthermore, no delamination of material was observed after salt spray tests for 96 hours and wet heat tests for 48 hours, according to the test methods of standards ISO 23160: 2011, NF S80-772, NF EN ISO 4611, NF EN ISO 9227.

This protective coating of a copper alloy substrate, in particular a brass or a bronze, may have mechanical protection characteristics and a decorative aspect similar to the characteristics of the coatings of the prior art.

This protective coating of a copper alloy substrate deposited on said copper alloy substrate can comprise a mechanical protective layer also forming a decorative layer.

Finally, the rate of release of nickel from this protective coating is, after verification, less than 0.04 μg/cm2/week (microgram per square centimeter per week) with a maximum limit of 0.88 μg/cm2/week (microgram per centimeter square per week). These objects therefore meet the standards in force in France to be able to be worn in direct contact with human skin.

The invention also relates to a process for depositing a protective coating of a copper alloy substrate on a copper alloy substrate by PVD technology, said process comprising the following steps:
a) said substrate is positioned on a substrate holder in a chamber,
b) a target consisting of at least one transition metal is installed in said chamber and the supply means of various gases are connected to the chamber, and a vacuum is applied,
c) said copper alloy substrate is dehumidified and descaled, in particular by heating and/or ionic descaling,
d) depositing, by PVD technology, a thin layer of said at least one transition metal on said substrate until a primer layer is formed,
e) the primer layer is bombarded with a mixture of argon ions and oxygen ions and a corrosion protection layer is formed by oxidizing the at least one transition metal of said primer layer so that said corrosion protection layer is formed by one part of said primer layer, and that said part of said primer layer is in the form of a combination of said at least one transition metal and said at least one oxidized transition metal, the primer layer deposited on said substrate then has a percentage of at least one oxidized transition metal relative to at least one transition metal initially deposited, said percentage being minimal, including being able to be zero, in the vicinity of the substrate, said percentage increasing, at least on average, monotonically from said substrate in the direction of increasing distance to the substrate.

According to an additional feature of step e) of the process described above, the minimum percentage of at least one transition metal oxidized relative to at least one transition metal initially deposited is 0%.

According to an additional feature of step e) of the process described above, the maximum percentage of at least one transition metal oxidized relative to at least one transition metal initially deposited is between 95 and 100%

In fact, the primer layer, once partially oxidized, has an oxide gradient that increases in moving away from the substrate to the corrosion protection layer formed, this corrosion protection layer having a maximum quantity of oxides.

According to an additional feature of step e) of the process described above, in particular during the at least partial oxidation process of the primer layer, argon atoms are inserted into the primer layer and the corrosion protection layer.

The quantity of argon atoms inserted during this process into said structures can be proportional to the percentage of the at least one transition metal oxidized relative to at least one transition metal initially deposited in said layers, and more particularly their layer structures. This quantity is minimal near the substrate, and increases as the substrate moves away to have maximum values at the corrosion protection layer.

According to a step according to step e) of the process described above and called step f), a mechanical protective layer is deposited, that is to say that an adhesion layer of the at least one transition metal from the target is deposited and a thin layer of a nitride or of a carbide or of an oxide or of an oxycarbide is then deposited, formed from the combination of at least one transition metal coming from the target, respectively nitrogen, or carbon, or oxygen, or oxygen and carbon, or nitrogen and carbon originating from gas comprising nitrogen or carbon or oxygen injected into the chamber by one or more gas supplies.

According to a step according to step e) and optionally f) described above and called step g), a decorative layer is deposited, that is to say that a thin layer is deposited. This may be a thin layer of a nitride or a carbide or an oxide or an oxycarbide or a nitrocarbide formed from the combination of at least one transition metal coming from the target with nitrogen, or carbon, or oxygen and carbon, or nitrogen and carbon coming from gas comprising nitrogen or carbon or oxygen injected into the chamber by one or more gas supplies. An adhesion layer made of at least one transition metal from the target can be deposited prior to the deposition of said layer described above in the paragraph.

A protective coating is thus simply produced which protects the substrate made of copper alloy and which may comprise a mechanical protective layer and/or a decorative layer from corrosion.

In fact, this process makes it possible to carry out all the steps of creating a protective coating by a single technology, PVD technology.

The protective coating can also be produced simply with the addition of at least one transition metal from one or more targets, which further facilitates the handling and the costs of manufacturing this coating.

Thus, handling is avoided and the risks of errors or accidents on the copper alloy objects or during the mounting of the coating layer of said objects made of copper alloy are reduced.

The use of a single technology and a single chamber makes it possible to propose a coating that coats a copper alloy substrate making it possible to protect said substrate made from copper alloy simply and at low cost.

### BRIEF DESCRIPTION OF THE SEVERAL VIEWS OF THE DRAWINGS

Other aims and advantages of the present invention will become apparent throughout the following description relating to the attached drawing illustrating embodiments.

The FIGURE is a schematic sectional view of a protective coating of a copper alloy substrate coating a copper alloy substrate, here a brass, said protective coating comprising a corrosion protection layer, a mechanical protective layer, and a decorative layer, according to a particular embodiment of the invention.

### DETAILED DESCRIPTION OF THE INVENTION

The invention relates to a protective coating 1 of a copper alloy substrate 2 deposited on a copper alloy substrate, here a brass. This substrate 2 may be a brass object, such as an ornament, a necklace element or a watch.

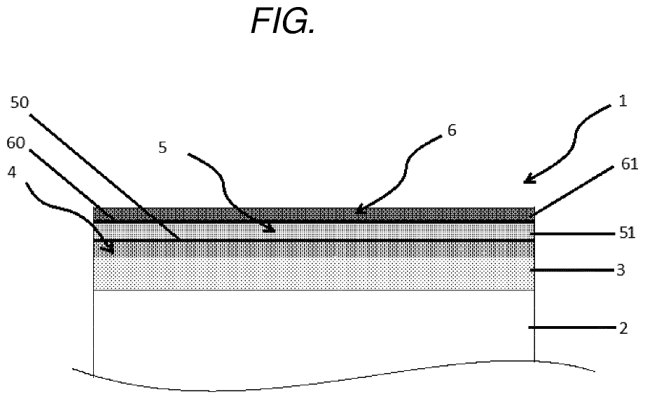

With reference to FIG. 1, the protective coating 1 is considered here as deposited above the brass substrate 2, and the top of said protective coating 1 deposited on said brass substrate 2 is located at the top of FIG. 1.

Said substrate 2 to be coated can be brushed, sandblasted, polished, or have any other surface treatment that does not modify its surface composition.

This protective coating 1 comprises a primer layer 3 deposited on said substrate 2 by deposition according to the PVD technology described above and known from the prior art.

The PVD technology used may in particular be a technology for physical vapor deposition by cathode magnetron sputtering, using a deposition chamber equipped with a target made of a transition metal, and gas lines allowing the supply of process gases such as argon and dihydrogen and reactive gases such as gases comprising nitrogen or oxygen, or carbon, such as dinitrogen, dioxygen or methane or acetylene.

The primer layer 3 deposited on said substrate 2 has, according to a particular embodiment, a thickness of between 0.2 micrometers and 1 micrometer.

The protective coating 1 comprises a corrosion protection layer 4. In fact, this corrosion protection layer 4 is formed by one part of the partially oxidized primer layer. This part of the partially oxidized primer layer forming a corrosion protection layer 4 comprises the transition metal of the primer layer 3 combined with the transition metal of the oxidized primer layer 3.

This oxide formed modifies the structure of the initial primer layer 3 on a part of said primer layer 3 and forms an anti-corrosion barrier protecting the substrate 2.

The primer layer 3 deposited on said substrate 2 has a percentage of at least one transition metal oxidized relative to at least one transition metal initially deposited that increases with distance from the substrate 2.

In fact, the primer layer 3 has, in the vicinity of the substrate 2, a minimum percentage, for example 0%, this percentage increasing as said substrate 2 becomes further away to reach a maximum percentage, between 95 and 100%, for example 99%, in the primer layer part 3 forming the corrosion protection layer 4.

The primer layer 3 comprising a part of at least one oxidized transition metal may also comprise argon atoms inserted into the structure of the primer layer 3 and of the corrosion protection layer 4.

The quantity of argon atoms inserted into said structures can be proportional to the percentage of the at least one transition metal oxidized relative to at least one transition metal initially deposited in said structures. This quantity is then minimal near the substrate 2, and increases as the distance from the substrate 2 increases to reach maximum values at the corrosion protection layer 4.

According to this particular embodiment, the corrosion protection layer 4 has a thickness of between 0.2 micrometers and 1 micrometer, and constitutes a part of the primer layer 3.

The transition metal of the primer layer 3 and of the corrosion protection layer 4 is titanium here, but another transition metal can be used, such as, for example, chromium, zirconium, yttrium or niobium, tungsten, vanadium, tantalum, or any other transition metal capable of oxidizing at least partially to form a protective layer against corrosion. The primer layer 3 and the corrosion protection layer 4 can be made not with a transition metal, but with an alloy of two or more transition metals, in particular titanium, chromium, zirconium, yttrium or niobium, tungsten, vanadium, tantalum, this alloy also being able to oxidize at least partially to satisfactorily form a corrosion protection layer.

A satisfactory protective layer refers to a protective layer that makes it possible to protect objects against corrosion according to 24-hour resistance tests, 96-hour salt spray tests and 48-hour wet heat tests, according to the test processes of the standards ISO 23160: 2011, NF S80-772, NF EN ISO 4611, NF EN ISO 9227.

The protective coating 1 may also comprise a mechanical protection layer 5 and a decorative layer 6.

As shown in FIG. 1, the mechanical protective layer 5 itself comprises an adhesion layer 50 coated by a functional layer 51 harder than the surface hardness of the bare brass.

The primer layer 50 is formed by depositing at least one transition metal using PVD technology on the corrosion protection layer 4. This at least one transition metal may be identical to that or one of those used to form the primer layer 3. This at least one transition metal may be different if another target of at least one other transition metal is inserted into the chamber and used to produce this layer.

The functional layer 51 can be formed by a deposition of a nitride using PVD technology on the adhesion layer 50. This nitride is formed by a plasma, combining at least one transition metal which can be identical to that or one of those used to form the primer layer 3, and nitrogen resulting from a gas comprising nitrogen. This at least one transition metal may be different if another target of at least one other transition metal is inserted into the chamber and used to produce this layer.

The functional layer 51 may alternatively be formed by a deposition of a carbide, an oxide, an oxycarbide or a nitrocarbide using the PVD technology instead of the deposition of nitride formed by combining at least one transition metal which can be identical to that or one of those used to form the primer layer 3 and respectively carbon, or oxygen, or oxygen and carbon, or nitrogen and carbon from gas comprising nitrogen or carbon or oxygen injected into the chamber.

As shown in FIG. 1, the decorative layer 6 here comprises an adhesion layer 60 coated by an aesthetic layer 61.

The adhesion layer 60 is formed by depositing a transition metal using PVD technology on the corrosion protection layer 4, or on the functional layer 51 in the case of a prior deposition of a mechanical protective layer 5 on the corrosion protection layer 4. This transition metal can be identical to that used to form the primer layer 3. This transition metal may be different if another target of another transition metal is inserted into the chamber and used to produce this layer.

According to one embodiment not shown here, the decorative layer 6 may not comprise an adhesion layer 60. The decorative layer 6 then comprises only an aesthetic layer 61.

The aesthetic layer 61 may be formed by depositing a nitride using PVD technology on the adhesion layer 60 of the decorative layer 6, or on the mechanical protective layer 5 if the decorative layer 6 does not comprise an adhesion layer 60. This nitride is formed by a plasma combining at least one transition metal which can be identical to that or one of those used to form the primer layer 3 and nitrogen resulting from a gas comprising nitrogen. This at least one transition metal may be different if another target of at least one other transition metal is inserted into the chamber and used to produce this layer.

The aesthetic layer 61 may alternatively be formed by a deposition of a carbide, an oxide, an oxycarbide or a nitrocarbide using PVD technology instead of the deposition of nitride, formed by combining at least one transition metal which can be identical to that or one of those used to form the primer layer 3 and respectively carbon, or oxygen, or oxygen and carbon, or nitrogen and carbon from gas comprising nitrogen or carbon or oxygen injected into the chamber.

It should be noted that to simplify the protective coating 1, the mechanical protection layer 5 may also be a decorative layer 6, according to an embodiment of the invention not shown here. The functional layer 51 is then also an aesthetic layer 61.

According to a particular embodiment, the protective coating 1 deposited on the substrate 2 comprises a mechanical protective layer 5 having an adhesion layer 50 with a thickness of between 0.05 and 0.2 micrometers, inclusive, and a functional layer 51 of thickness between 0.2 and 1 micrometer, inclusive.

The protective coating 1 deposited on substrate 2 may also comprise a decorative layer 6 having an adhesion layer 60 with a thickness of between 0.05 and 0.2 micrometers, inclusive, and an aesthetic layer 61 with a thickness of between 0.2 and 1 micrometer, inclusive.

As shown in FIG. 1, the decorative layer 6 coats the mechanical protective layer 5.

The substrate 2 coated with a protective coating 1 according to the invention was subjected to wear tests carried out on Turbula®, to adhesion tests, including the grid test, and climatic tests involving artificial sweat, salt spray, wet heat and wet heat in the presence of leather.

These tests showed a satisfactory result of protecting the substrate 2 by the protective coating 1 when it coats said substrate 2.

The invention also relates to a process for depositing a protective coating of a copper alloy substrate on a copper alloy substrate, in particular a brass or a bronze, by PVD technology. An example of a process is described below.

This process comprises the following steps:

a) said substrate 2 is positioned on a substrate holder in a chamber used to carry out a deposition by PVD technology. This substrate 2 may have been washed and/or degreased with different detergents, rinsed and dried before being positioned in the substrate holder. This substrate 2 is here a brass composed of 58% copper and 42% zinc by mass.

b) a target made of at least one transition metal is installed in the chamber. The at least one transition metal is in the example described below of titanium, Ti. The chamber is also connected to the chamber of the various gases, in particular argon gas, dioxygen gas, dihydrogen gas and dinitrogen gas. The gas supply means are for example gas supply networks connected to gas cylinders. Vacuum pumps are also used to make the vacuum in the chamber up to a starting pressure between 5.10-5 and 1.10-7 millibar, inclusive.

c) the brass substrate 2 is prepared, that is to say that said substrate 2 is dehumidified by heating, and said substrate 2 is descaled in order in particular to remove the oxides that can be present on said substrate 2; this descaling is carried out by ionic descaling. Heating is carried out between 200 to 300 degrees Celsius, inclusive, to eliminate possible moisture residue and improve adhesion to the substrate 2. Ion descaling can be carried out by passing through the substrate 2 a plasma obtained from an argon/hydrogen mixture, with an argon/hydrogen ratio by volume comprised between a ratio 98/2 and an 80/20 ratio, inclusive, and this to prepare the surface condition of the substrate 2.

d) a thin layer of titanium is deposited by PVD on the substrate 2 until a primer layer 3 is formed. To do this, titanium is transferred from the target to the substrate 2. This deposition is done here by cathode sputtering for a time between 10 to 30 minutes, inclusive, under an argon gas flush with a flow rate of between 200 to 300 cm3/minute, inclusive, at an argon gas density defined by standard temperature and pressure conditions, that is 101.325 kPa absolute (14.6959 psia) and at a temperature of 0° C. (32° F.). The deposition is carried out here at a total pressure of between 5.10-3 to 3.10-2 millibars, without a bias voltage, without heating and at a power of about 4 kilowatts, with an electrical intensity of 7 amps. The primer layer 3 thus formed has a thickness of between 0.2 micrometers and 1 micrometer, inclusive.

e) once the primer layer 3 is formed on said substrate 2, the top of said primer layer 3 is bombarded for a time between 3 and 10 minutes, inclusive, with a plasma of argon ions and oxygen ions. In fact, a mixture of argon and oxygen is used with a volume ratio of oxygen/argon between 0.15 and 0.5. The total pressure in the chamber is then 5.10-3 to 3.10-2 millibars, and bombardment is carried out under a pulsed bias voltage of between 400 and 700 volts, inclusive. A corrosion protection layer 4 formed by the modification of at least one part of the primer layer 3 is thus formed. This at least one part of the primer layer 3 comprises titanium combined with oxidized titanium. This at least one part of the primer layer 3 may also comprise other compounds formed by other combinations of titanium atoms alone, oxygen atoms alone or titanium atoms combined with oxygen atoms.

f) according to an additional and optional step, a mechanical protection layer 5 is produced on the corrosion protection layer 4. To do this, a thin layer of titanium is deposited to form an adhesion layer 50 with a thickness of between 0.05 and 0.2 micrometers, inclusive. Once this adhesion layer 50 has been produced, a layer of titanium nitride is deposited resulting from the combination of titanium atoms coming from the target with nitrogen atoms from a nitrogen gas in the chamber. A mechanical protection layer 5 is thus formed that has a thickness of between 0.2 and 1 micrometers,

g) according to another additional and optional step, a decorative layer 6 is produced on the corrosion protection layer 4, or on the mechanical protection layer 5 in the case where the process performs step f). To do this, a thin layer of titanium is deposited to form an adhesion layer 60 with a thickness of between 0.05 and 0.2 micrometers, inclusive. Once this adhesion layer 60 has been produced, a layer of titanium nitride is deposited resulting from the combination of titanium atoms coming from the target with nitrogen atoms from a gas comprising nitrogen, such as for example nitrogen gas in the chamber. A decorative layer 6 is thus formed and which has a thickness of between 0.2 and 1 micrometers, inclusive.

According to a feature of the invention, during the at least partial oxidation process of the primer layer 3 described above, the oxidation is varied so that said primer layer 3 has a percentage of at least one transition metal oxidized relative to at least one transition metal initially deposited, which increases with the distance from the substrate 2, having an oxidation gradient. Thus, once the oxidation step has been carried out, the primer layer 3 has, in the vicinity of the substrate 2, a minimum percentage, for example 0 to 1%, this percentage increasing as said substrate 2 becomes further away to reach a maximum percentage of between 95 and 100%, for example 99%, in the primer layer part 3 which forms the corrosion protection layer 4.

According to one feature of the invention, during the at least partial oxidation process of the primer layer 3 described above, argon atoms are inserted into the primer layer 3 and the corrosion protection layer 4.

According to a feature of the invention, the quantity of argon atoms inserted during this process in said layers is proportional to the percentage of the at least one transition metal oxidized relative to at least one transition metal initially deposited in said layers. This quantity is minimal near the substrate 2, and increases as the distance from the substrate 2 grows to have maximum values at the corrosion protection layer 4.

According to an alternative embodiment not shown here, the mechanical protection layer 5 formed by step f) is also a decorative layer 6. This reduces the total thickness of the protective coating 1.

This type of deposition of a mechanical protection layer 5 or decorative layer 6 is known from the prior art and is carried out according to the modalities known to the person skilled in the art.

A titanium nitride layer is used to obtain a decorative layer with a yellow color. In order to obtain a white decorative layer, a layer of chromium nitride can be deposited. It is then necessary to provide, in step b) of the process described above, the insertion also of a chromium target into the chamber in addition to the titanium target to form a chromium adhesion layer 60 and then an aesthetic layer 61 of chromium nitride according to step g). This decorative chromium layer can coat the titanium protective layer made of titanium and titanium nitride, as shown in FIG. 1.

The decorative layer 6 may of course have other colors depending on the metal or alloy of metals used and deposited to form said decorative layer 6.

Of course, one or more transition metals can also be used other than titanium to form a protective coating 1 deposited on a copper alloy substrate 2, in particular a brass.

It is also possible to use a transition metal other than titanium to form all or part of the corrosion protection layer 4, the mechanical protective layer 5 or the decorative layer 6 of a protective coating 1 deposited on a substrate 2 made of copper alloy, in particular a brass.

It is also possible, instead of a layer of nitride, a layer of carbide, oxide, oxycarbide, nitrogen carbide by combining not nitrogen atoms derived from a gas comprising nitrogen, but by combining oxygen and/or carbon and/or nitrogen from one or more gases respectively comprising oxygen, carbon or nitrogen.

The various steps of the process for manufacturing the coating with or without a mechanical protective layer 5 and/or decorative layer 6 are made in a single vacuum load and without venting the substrate 2.

Of course, this process can apply to several substrates at once, in particular mounted on a substrate holder having mobile parts in the chamber, and can use several identical or different targets.

The process described above makes it possible to produce a protective coating 1 deposited on a substrate 2 made of copper alloy, having all or part of the characteristics of the protective coating 1 deposited on a substrate 2 made of copper alloy according to the invention described above.

A protective coating 1 deposited on a copper alloy substrate 2 according to the invention described above can be carried out by implementing the process described above, including or not including step f) and/or step g).

This process for depositing a protective coating on a copper alloy substrate is particularly suitable for a brass or bronze substrate. This protective coating is particularly suitable for protecting a brass or bronze substrate from corrosion.

We claim:

1. A protective coating for a copper alloy substrate, comprising:
a primer layer to be deposited on said copper alloy substrate, said primer layer being comprised of a layer of at least one transition metal; and
a corrosion protection layer,
wherein said corrosion protection layer is comprised of at least one part of said primer layer,
wherein said at least one part of said primer layer is comprised of said at least one transition metal and at least one oxidized transition metal, and
wherein said primer layer has a percentage of at least one oxidized transition metal related to at least one transition metal deposited initially, said percentage being minimal, including being able to be zero, in the vicinity of the substrate said percentage increasing, at least on average, monotonically from said substrate in the direction of the increasing distance to said substrate.

2. The protective coating, according to claim 1, wherein the primer layer and the corrosion protection layer are comprised of argon atoms.

3. The protective coating, according to claim 1, further comprising:
a mechanical protective layer coating the corrosion protection layer.

4. The protective coating, according to claim 3, wherein the mechanical protective layer comprises an adhesion layer and a functional layer, the adhesion layer being a thin layer of at least one same transition metal as that used to form the primer layer, the functional layer being a thin layer of a nitride of a same at least one transition metal as that used to form the primer layer.

5. The protective coating, according to claim 3, wherein the mechanical protective layer comprises an adhesion layer and a functional layer, the adhesion layer being a layer of at least one same transition metal as that used to form the primer layer, the functional layer being a layer of an oxide or a carbide or an oxycarbide or a nitrogen carbide of a same at least one transition metal as that used to form the primer layer.

6. The protective coating, according to claim 3, further comprising: a decorative layer coating the mechanical protective layer.

7. The protective coating, according to claim 6, wherein the decorative layer comprises an aesthetic layer, the aesthetic layer being a layer of a nitride of the same at least one transition metal as that used to form the primer layer.

8. The protective coating, according to claim 7, wherein the decorative layer comprises an aesthetic layer, the aesthetic layer being a layer of an oxide or carbide or oxycarbide or a nitrogen carbide of the same at least one transition metal as that used to form the primer layer.

9. The protective coating, according to claim 1, wherein said at least one transition metal is titanium.

10. The protective coating, according to claim 1, wherein said at least one transition metal of said primer layer is chromium, zirconium, yttrium, niobium, tungsten, vanadium, tantalum, or wherein said primer layer of said protective coating is comprised of a layer of an alloy of at least two transition metals from titanium, chromium, zirconium, yttrium, niobium, tungsten, vanadium, and tantalum.

11. A process for depositing a protective coating of a copper alloy substrate on a copper alloy substrate by PVD technology, said process comprising the following steps:
a) positioning said substrate on a substrate holder in a chamber,
b) installing a target being comprised of at least one transition metal in said chamber, supply means of various gases are connected to the chamber, and a vacuum is applied,
c) dehumidifying and descaling said copper alloy substrate by heating and/or ionic descaling,
d) depositing a layer of said at least one transition metal on said substrate by PVD technology until a primer layer is formed,
e) bombarding the primer layer with a mixture of argon ions and oxygen ions and forming a corrosion protection layer by oxidizing the at least one transition metal of said primer layer so that said corrosion protection layer is formed by one part of said primer layer,
wherein said part of said primer layer is in the form of a combination of said at least one transition metal and said at least one oxidized transition metal,
wherein oxidation is varied so that the primer layer deposited on said substrate has a percentage of at least one oxidized transition metal relative to at least one transition metal initially deposited, said percentage being minimal, including being able to be zero, in the vicinity of the substrate, said percentage increasing, at least on average, monotonically from said substrate in the direction of increasing distance to said substrate.

12. The process for depositing a protective coating of a brass substrate, according to claim 11, wherein the step e) comprises: inserting argon atoms into the primer layer and the corrosion protection layer.

13. The process for depositing a protective coating of a brass substrate, according to claim 11, further comprising the step of: depositing a mechanical protective layer on the corrosion protection layer.

14. The process for depositing a protective coating of a brass substrate, according to claim 11, further comprising the step of: depositing a decorative layer on the corrosion protection layer.

15. The process for depositing a protective coating of a brass substrate, according to claim 13, further comprising the step of: depositing a decorative layer on the mechanical protective layer.
